(19) United States
(12) Patent Application Publication
(10) Pub. No.: US 2025/0295041 A1
(43) Pub. Date: Sep. 18, 2025

(54) MAGNETIC MEMORY DEVICE

(71) Applicants: Kioxia Corporation, Tokyo (JP); SK hynix Inc., Icheon-si (KR)

(72) Inventors: Tadaaki OIKAWA, Seoul (KR); Kazuya SAWADA, Seoul (KR); Soichi OIKAWA, Seoul (KR); Kenji FUKUDA, Seoul (KR); Jinwon JUNG, Icheon-si (KR); Junghyeok KWAK, Icheon-si (KR)

(73) Assignees: Kioxia Corporation, Tokyo (JP); SK hynix Inc., Icheon-si (KR)

(21) Appl. No.: 18/828,918

(22) Filed: Sep. 9, 2024

(30) Foreign Application Priority Data
Mar. 14, 2024 (JP) 2024-040336

(51) Int. Cl. H10N 50/85; G11C 11/16; H10B 61/00; H10N 50/10

(52) U.S. Cl. CPC H10N 50/85; G11C 11/161; H10B 61/10; H10B 61/20; H10N 50/10; G11C 11/1673; G11C 11/1675

(57) ABSTRACT

According to one embodiment, a magnetic memory device includes first, second, third, fourth, fifth, sixth and seventh non-magnetic layers, and first, second and third ferromagnetic layers. The first ferromagnetic layer, the second non-magnetic layer, the second ferromagnetic layer, the third non-magnetic layer, the third ferromagnetic layer, the fourth non-magnetic layer, the fifth non-magnetic layer, the sixth non-magnetic layer, and the seventh non-magnetic layer are provided in this order above the first non-magnetic layer. The first non-magnetic layer includes silicon. The fourth non-magnetic layer includes magnesium and oxygen. The fifth non-magnetic layer includes molybdenum. The sixth non-magnetic layer includes hafnium. The seventh non-magnetic layer includes ruthenium.

### CROSS-REFERENCE TO RELATED APPLICATIONS

This application is based upon and claims the benefit of priority from Japanese Patent Application No. 2024-040336, filed Mar. 14, 2024, the entire contents of which are incorporated herein by reference.

### FIELD

Embodiments described herein relate generally to a magnetic memory device.

### BACKGROUND

There is known a magnetic memory device (e.g., MRAM: magnetoresistive random access memory) that uses a magnetoresistance effect element as a memory element.

### BRIEF DESCRIPTION OF THE DRAWINGS

FIG. 1 is a block diagram showing the configuration of a memory system including a magnetic memory device according to a first embodiment.

FIG. 2 is a circuit diagram showing a memory cell array of the magnetic memory device according to the first embodiment.

FIG. 3 is a perspective view showing the structure of the memory cell array of the magnetic memory device according to the first embodiment.

FIG. 4 is a cross-sectional view of a variable resistance element of the magnetic memory device according to the first embodiment.

FIG. 5 is a diagram showing cross-sectional structures and characteristics of metal cap layers in the first embodiment and Comparative Example 1.

FIG. 6 is a cross-sectional view of a variable resistance element of a magnetic memory device according to a second embodiment.

FIG. 7 is a diagram showing cross-sectional structures of metal cap layers and buffer layers in the second embodiment and Comparative Examples 2-4.

FIG. 8 is a diagram showing relationships between exchange coupling magnetic fields and magnetoresistance ratios in the second embodiment and Comparative Examples 2-4.

FIG. 9 is a cross-sectional view of a variable resistance element of a magnetic memory device according to a third embodiment.

FIG. 10 is a diagram showing cross-sectional structures and characteristics of metal cap layers and oxide cap layers in the third embodiment and Comparative Examples 5-7.

FIG. 11 is a cross-sectional view of a variable resistance element included in a memory cell of a magnetic memory device according to a fourth embodiment.

FIG. 12 is a cross-sectional view of a variable resistance element included in a memory cell of a magnetic memory device according to a fifth embodiment.

FIG. 13 is a cross-sectional view of a variable resistance element included in a memory cell of a magnetic memory device according to a sixth embodiment.

### DETAILED DESCRIPTION

In general, according to one embodiment, a magnetic memory device includes a first non-magnetic layer, a first ferromagnetic layer, a second non-magnetic layer, a second ferromagnetic layer, a third non-magnetic layer, a third ferromagnetic layer, a fourth non-magnetic layer, a fifth non-magnetic layer, a sixth non-magnetic layer, and a seventh non-magnetic layer. The first non-magnetic layer includes silicon (Si). The first ferromagnetic layer is provided above the first non-magnetic layer. The second non-magnetic layer is provided above the first ferromagnetic layer. The second ferromagnetic layer is provided above the second non-magnetic layer. The third non-magnetic layer is provided above the second ferromagnetic layer. The third ferromagnetic layer is provided above the third non-magnetic layer. The fourth non-magnetic layer is provided above the third ferromagnetic layer and includes magnesium (Mg) and oxygen (O). The fifth non-magnetic layer is provided above the fourth non-magnetic layer and includes molybdenum (Mo). The sixth non-magnetic layer is provided above the fifth non-magnetic layer and includes hafnium (Hf). The seventh non-magnetic layer is provided above the sixth non-magnetic layer and includes ruthenium (Ru).

Embodiments will be described with reference to the accompanying drawings. In the descriptions below, structural elements with similar functions and configurations will be denoted by the same reference symbols. The embodiments described below merely illustrate an exemplary apparatus and method that implement the technical ideas of the embodiments. The technical ideas are not limited to the element materials, shapes, structures, arrangements etc. described below.

### 1. FIRST EMBODIMENT

First, a memory system including a magnetic memory device of a first embodiment will be described.

### 1.1 Memory System

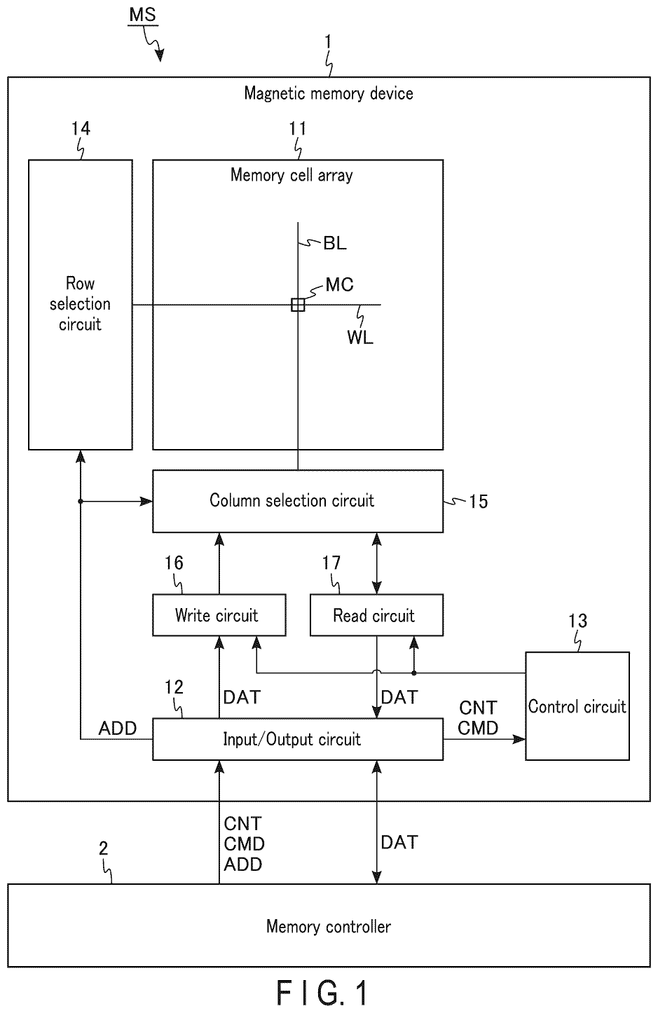

An example of a memory system will be described with reference to FIG. 1. FIG. 1 is a block diagram showing the configuration of a memory system MS including a magnetic memory device according to the first embodiment.

As shown in FIG. 1, the memory system MS includes a magnetic memory device 1 and a memory controller 2. The magnetic memory device 1 operates under the control of the memory controller 2. The memory controller 2 can instruct the magnetic memory device 1 to perform a read operation, a write operation, etc. in response to a request (or a command) from an external host device.

The magnetic memory device 1 is a type of resistance change memory. The magnetic memory device 1 is a memory device that uses MTJ (magnetic tunnel junction) elements as memory cells. The MTJ elements utilize the magnetoresistance effect caused by a magnetic tunnel junction. The MTJ elements are referred to as magnetoresistance effect elements as well.

The magnetic memory device 1 includes, for example, a memory cell array 11, an input/output circuit 12, a control circuit 13, a row selection circuit 14, a column selection circuit 15, a write circuit 16, and a read circuit 17.

The memory cell array 11 includes a plurality of memory cells MC, a plurality of word lines WL, and a plurality of bit lines BL. FIG. 1 shows one set consisting of a memory cell MC, a word line WL, and a bit line BL. The memory cells MC can store data in a nonvolatile manner. Each memory cell MC is coupled between one word line WL and one bit line BL, and is associated with a pair consisting of a row and a column. A row address is assigned to the word line WL. A column address is assigned to the bit line BL. One or more memory cells MC can be specified by selecting one row and one or more columns.

The input/output circuit 12 is coupled to the memory controller 2 and controls communications between the magnetic memory device 1 and the memory controller 2. The input/output circuit 12 transfers a control signal CNT and a command CMD received from the memory controller 2 to the control circuit 13. Also, the input/output circuit 12 transfers a row address and a column address included in an address signal ADD received from the memory controller 2 to the row selection circuit 14 and the column selection circuit 15, respectively. The input/output circuit 12 transfers data DAT (write data) received from the memory controller 2 to the write circuit 16. The input/output circuit 12 transfers data DAT (read data) received from the read circuit 17 to the memory controller 2.

The control circuit 13 controls the overall operation of the magnetic memory device 1. For example, the control circuit 13 executes a read operation, a write operation, etc., based on the control indicated by the control signal CNT and the command CMD. For example, in a write operation, the control circuit 13 supplies the write circuit 16 with a voltage used for data write. In addition, in a read operation, the control circuit 13 supplies the read circuit 17 with a voltage used for data read.

The row selection circuit 14 is coupled to a plurality of word lines WL. The row selection circuit 14 selects one word line WL specified by a row address. The selected word line WL is electrically coupled, for example, to a driver circuit (not shown).

The column selection circuit 15 is coupled to a plurality of bit lines BL. The column selection circuit 15 selects one or more bit lines BL specified by a column address. The selected bit lines BL are electrically coupled, for example, to a driver circuit (not shown).

The write circuit 16 supplies a voltage used for data write to the column selection circuit 15, based on the control of the control circuit 13 and the data DAT (write data) received from the input/output circuit 12. In a case where a current based on the write data flows through the memory cell MC, a desired data is written to the memory cell MC.

The read circuit 17 includes a sense amplifier. The read circuit 17 supplies the column selection circuit 15 with a voltage used for data read, based on the control of the control circuit 13. The sense amplifier determines the data stored in the memory cell MC, based on the voltage or current of the selected bit line BL. Furthermore, the read circuit 17 transfers data DAT (read data) corresponding to the determination result to the input/output circuit 12.

### 1.2 Magnetic Memory Device

### 1.2.1 Circuit Configuration of Memory Cell Array

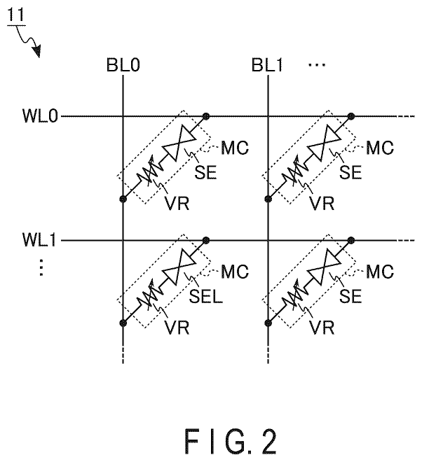

An example of the circuit configuration of the memory cell array 11 included in the magnetic memory device 1 will be described with reference to FIG. 2. FIG. 2 is a circuit diagram showing the circuit configuration of the memory cell array 11 included in the magnetic memory device 1 of the first embodiment. FIG. 2 shows WL0 and WL1 of the plurality of word lines WL, and BL0 and BL1 of the plurality of bit lines BL.

As shown in FIG. 2, one memory cell MC is coupled between WL0 and BL0, WL0 and BL1, WL1 and BL0, and WL1 and BL1. The plurality of memory cells MC are arranged, for example, in a matrix pattern in the memory cell array 11.

Each memory cell MC includes a variable resistance element VR and a switching element SE. The variable resistance element VR and the switching element SE are coupled in series between the associated bit line BL and word line WL. For example, one end of the variable resistance element VR is coupled to the bit line BL. The other end of the variable resistance element VR is coupled to one end of the switching element SE. The other end of the switching element SE is coupled to the word line WL. The coupling relationship of the variable resistance element VR and the switching element SE may be reversed between the bit line BL and the word line WL. That is, one end of the variable resistance element VR is coupled to the word line WL, and the other end of the variable resistance element VR is coupled to one end of the switching element SE. The other end of the switching element SE may be coupled to the bit line BL.

The variable resistance element VR corresponds to an MTJ element. The variable resistance element VR can store data in a nonvolatile manner, based on the resistance value thereof. For example, a memory cell MC including a variable resistance element VR in a high resistance state stores data “1.” A memory cell MC including a variable resistance element VR in a low resistance state stores data “0.” Allocation of data associated with the resistance value of the variable resistance element VR may be set differently. The resistance state of the variable resistance element VR can change depending on the current flowing through the variable resistance element VR.

The switching element SE is, for example, a bidirectional diode. The switching element SE functions as a selector that controls the supply of current to the associated variable resistance element VR. Specifically, the switching element SE included in a certain memory cell MC is in the off state in a case where the voltage applied to the memory cell MC is lower than the threshold voltage of the switching element SE, and is in the on state in a case where that voltage is equal to or higher than the threshold voltage of the switching element SE. The switching element SE in the off state functions as an insulator having a high resistance value. In a case where the switching element SE is in the off state, the flow of current is suppressed between the word line WL and the bit line BL coupled to the memory cell MC. The switching element SE in the on state functions as a conductor having a low resistance value. In a case where the switching element SE is in the on state, a current flows between the word line WL and bit line BL coupled to the memory cell MC. In other words, the switching element SE can switch whether or not to permit the flow of a current depending on the magnitude of the voltage applied to the memory cell MC, regardless of the direction in which the current flows. It should be noted that another element such as a transistor may be used as the switching element SE.

### 1.2.2 Structure of Memory Cell Array

An example of the structure of the memory cell array 11 included in the magnetic memory device 1 will be described below. In the description below, an XYZ orthogonal coordinate system is used. The X direction corresponds to the direction in which the bit line BL extends. The Y direction corresponds to the direction in which the word line WL extends. The Z direction corresponds to the direction vertical to the surface of the semiconductor substrate used to form the magnetic memory device 1. The term “down” and its derivatives and related words indicate a position of a smaller coordinate on the Z axis. The term “up” and its derivatives and related words indicate a position of a larger coordinate on the Z axis. Hatching is added to the perspective view where appropriate. The hatching added to the perspective view is not necessarily related to the materials or characteristics of the hatched components. In the perspective view and cross-sectional views, illustration of configurations such as interlayer insulating films is omitted.

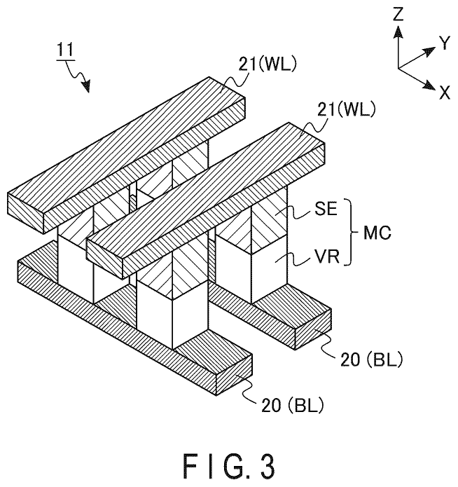

An example of the three-dimensional structure of the memory cell array 11 included in the magnetic memory device 1 will be described with reference to FIG. 3. FIG. 3 is a perspective view showing the structure of the memory cell array 11 included in the magnetic memory device 1 of the first embodiment.

As shown in FIG. 3, the memory cell array 11 includes a plurality of conductive layers 20, a plurality of conductive layers 21, and a plurality of memory cells MC.

Each of the plurality of conductive layers 20 has a portion extending in the X direction. The plurality of conductive layers 20 are arranged side by side in the Y direction and are spaced apart from each other. Each conductive layer 20 is used as a bit line BL.

Each of the plurality of conductive layers 21 has a portion extending in the Y direction. The plurality of conductive layers 21 are arranged side by side in the X direction and are spaced apart from each other. Each conductive layer 21 is used as a word line WL.

An interconnect layer including the plurality of conductive layers 21 is provided above an interconnect layer including the plurality of conductive layers 20. One memory cell MC is provided at each of the intersections between the plurality of conductive layers 20 and the plurality of conductive layers 21. In other words, each memory cell MC is provided between the associated bit line BL and word line WL. Each memory cell MC has a columnar structure. In this example, the variable resistance element VR is provided on the conductive layer 20. The switching element SE is provided on the variable resistance element VR. The switching element SE is overlaid with the conductive layer 21.

Although a description was given of an example in which the variable resistance element VR is provided below the switching element SE, the variable resistance element VR may be provided above the switching element SE, depending on the circuit configuration of the memory cell array 11.

### 1.2.3 Cross-Sectional Structure of Variable Resistance Element

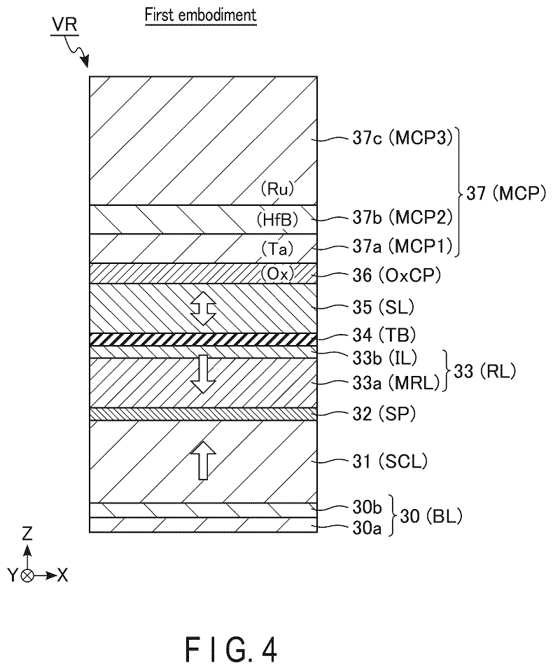

Next, the cross-sectional structure of the variable resistance element VR included in the memory cell MC will be described with reference to FIG. 4. FIG. 4 is a cross-sectional view of the variable resistance element VR included in the memory cell MC of the magnetic memory device 1 of the first embodiment.

As shown in FIG. 4, the variable resistance element VR includes, for example, a non-magnetic layer 30, a ferromagnetic layer 31, a non-magnetic layer 32, a ferromagnetic layer 33, a non-magnetic layer 34, a ferromagnetic layer 35, a non-magnetic layer 36, and a non-magnetic layer 37. In FIG. 4 and subsequent Figures, the magnetization directions of the magnetic layers are indicated by arrows. Bidirectional arrows indicate that the magnetization directions are variable.

The non-magnetic layer 30, the ferromagnetic layer 31, the non-magnetic layer 32, the ferromagnetic layer 33, the non-magnetic layer 34, the ferromagnetic layer 35, the non-magnetic layer 36 and the non-magnetic layer 37 are stacked in this order from the conductive layer 20 (bit line BL) side toward the conductive layer 21 (word line WL) side (in the Z direction).

Specifically, the non-magnetic layer 30 is provided above the conductive layer 20 (in the Z direction). The ferromagnetic layer 31 is provided above the non-magnetic layer 30. The non-magnetic layer 32 is provided above the ferromagnetic layer 31. The ferromagnetic layer 33 is provided above the non-magnetic layer 32. The non-magnetic layer 34 is provided above the ferromagnetic layer 33. The ferromagnetic layer 35 is provided above the non-magnetic layer 34. The non-magnetic layer 36 is provided above the ferromagnetic layer 35. The non-magnetic layer 37 is provided above the non-magnetic layer 36. The conductive layer 21 is provided above the non-magnetic layer 37.

In other words, the ferromagnetic layer 33 is provided between the ferromagnetic layer 31 and the ferromagnetic layer 35. The non-magnetic layer 34 is provided between the ferromagnetic layer 33 and the ferromagnetic layer 35. The non-magnetic layer 32 is provided between the ferromagnetic layer 31 and the ferromagnetic layer 33. The ferromagnetic layer 31 is provided between the non-magnetic layer 30 and the non-magnetic layer 32. The non-magnetic layer 30 is provided between the conductive layer 20 and the ferromagnetic layer 31. The ferromagnetic layer 35 is provided between the non-magnetic layer 34 and the non-magnetic layer 36. The non-magnetic layer 36 is provided between the ferromagnetic layer 35 and the non-magnetic layer 37. The non-magnetic layer 37 is provided between the non-magnetic layer 36 and the conductive layer 21.

The non-magnetic layer 30 is a non-magnetic conductor. The non-magnetic layer (buffer layer BL) 30 functions as a layer for controlling the ferromagnetic layer 31 formed thereon to have a desired crystal orientation. The non-magnetic layer 30 includes a first layer 30a and a second layer 30b. The second layer 30b is provided above the first layer 30a. In other words, the second layer 30b is provided between the first layer 30a and the ferromagnetic layer 31.

The first layer 30a has an amorphous structure. The first layer 30a contains hafnium (Hf) or hafnium boron (HfB).

The second layer 30b has a body centered cubic (BCC) crystal structure, and has a [110] plane of the BCC crystal structure in the direction perpendicular to the stacking direction of the stacked structure [100]. By using such a second layer 30b, the ferromagnetic layer 31 can be well oriented in the face centered cubic (FCC) [111] plane or the hexagonal close packed (HCP) [0001] plane. This can improve the perpendicular magnetic anisotropy etc. of the ferromagnetic layer 31. The second layer 30b can contain at least one element selected from molybdenum (Mo), tungsten (W), and tantalum (Ta). That is, the second layer 30b may be a molybdenum (Mo) layer, a tungsten (W) layer, or a tantalum (Ta) layer. The second layer 30b may be an alloy layer of two or more elements selected from molybdenum (Mo), tungsten (W), and tantalum (Ta).

Although the non-magnetic layer 30 is shown as having two layers in the example shown in FIG. 4, it may be a stacked structure made up of three or more layers.

The ferromagnetic layer 31 is a ferromagnetic conductor. The ferromagnetic layer 31 has an easy magnetization axis direction perpendicular to the film surface. In the example shown in FIG. 4, the magnetization direction of the ferromagnetic layer 31 faces the ferromagnetic layer 33. The magnitude of the magnetic field required to reverse the magnetization direction of the ferromagnetic layer 31 is, for example, larger than that of the ferromagnetic layer 33. The leakage magnetic field from the ferromagnetic layer 31 reduces the effect which the leakage magnetic field from the ferromagnetic layer 33 may have on the magnetization direction of the ferromagnetic layer 35. In other words, the ferromagnetic layer 31 functions as a shift canceling layer SCL.

The ferromagnetic layer 31 contains at least one element selected from the group consisting of iron (Fe), cobalt (Co), and nickel (Ni). The ferromagnetic layer 31 may further contain, as impurities, at least one element selected from the group consisting of boron (B), phosphorus (P), carbon (C), aluminum (Al), silicon (Si), tantalum (Ta), molybdenum (Mo), chromium (Cr), hafnium (Hf), tungsten (W), and titanium (Ti). Specifically, the ferromagnetic layer 31 may contain cobalt iron boron (CoFeB). The ferromagnetic layer 31 may contain at least one binary compound selected from the group consisting of iron boride (FeB), cobalt platinum (CoPt), cobalt nickel (CoNi), and cobalt palladium (CoPd).

The non-magnetic layer 32 is a non-magnetic conductor. The non-magnetic layer 32 is used as a spacer layer SP between the ferromagnetic layer 31 and the ferromagnetic layer 33, and is antiferromagnetically coupled to the ferromagnetic layer 31. As a result, the magnetization direction of the ferromagnetic layer 31 is fixed in an antiparallel direction with respect to the magnetization direction of the ferromagnetic layer 33. This coupling structure among the ferromagnetic layer 31, the non-magnetic layer 32 and the ferromagnetic layer 33 is referred to as a synthetic anti-ferromagnetic (SAF) structure. The non-magnetic layer 32 contains at least one element selected from the group consisting of, for example, ruthenium (Ru), osmium (Os), iridium (Ir), vanadium (V), and chromium (Cr).

The ferromagnetic layer 33 is a ferromagnetic conductor. The ferromagnetic layer 33 has an easy magnetization axis direction perpendicular to the film surface. The magnetization direction of the ferromagnetic layer 33 is fixed on the side of the ferromagnetic layer 31 or on the side of the ferromagnetic layer 35. In the example shown in FIG. 4, the magnetization direction of the ferromagnetic layer 33 is fixed on the side of the ferromagnetic layer 31. As a result, ferromagnetic layer 33 is used as a reference layer RL of the MTJ element. The reference layer RL is referred to as a “pinned layer” or “fixed layer” as well.

The ferromagnetic layer 33 includes ferromagnetic layers 33a and 33b. The ferromagnetic layer 33a is provided above the non-magnetic layer 32. The ferromagnetic layer 33b is provided above the ferromagnetic layer 33a. The ferromagnetic layer 33a functions as a main reference layer MRL. The ferromagnetic layer 33b functions as an interface layer IL between the non-magnetic layer 34 and the main reference layer MRL.

The ferromagnetic layer 33a contains at least one element selected from the group consisting of iron (Fe), cobalt (Co), and nickel (Ni). The ferromagnetic layer 33a may contain, as impurities, at least one element selected from the group consisting of boron (B), phosphorus (P), carbon (C), aluminum (Al), silicon (Si), tantalum (Ta), molybdenum (Mo), chromium (Cr), hafnium (Hf), tungsten (W), and titanium (Ti). Specifically, the ferromagnetic layer 33a may include cobalt iron boron (CoFeB). The ferromagnetic layer 33a may contain at least one binary compound selected from the group consisting of iron boride (FeB), cobalt platinum (CoPt), cobalt nickel (CoNi), and cobalt palladium (CoPd). The ferromagnetic layer 33b may contain, for example, cobalt iron boron (CoFeB) or iron boride (FeB).

The non-magnetic layer 34 is a non-magnetic insulator. The non-magnetic layer 34 forms a magnetic tunnel junction together with the ferromagnetic layers 33 and 35. That is, the non-magnetic layer 34 functions as a tunnel barrier layer TB of the MTJ element. The non-magnetic layer 34 also functions as a seed material in the crystallization process of the ferromagnetic layers 33 and 35 included in the manufacturing process of the magnetic memory device 1. The seed material corresponds to a material that serves as a nucleus for growing a crystalline film from the interface between the ferromagnetic layers 33 and 35. The non-magnetic layer 34 contains at least one element, or an oxide of a compound thereof, selected from the group consisting of magnesium (Mg), aluminum (Al), zinc (Zn), titanium (Ti), and LSM (lanthanum-strontium-manganese).

The ferromagnetic layer 35 is a ferromagnetic conductor. The ferromagnetic layer 35 has an easy magnetization axis direction perpendicular to the film surface. The magnetization direction of the ferromagnetic layer 35 is directed either toward the ferromagnetic layer 33 side or the non-magnetic layer 36 side. The magnetization direction of the ferromagnetic layer 35 is configured to be more easily reversible than that of ferromagnetic layer 33. Thus, the ferromagnetic layer 35 is used as a storage layer SL of the MTJ element. The storage layer SL is referred to as a “free layer” as well.

The ferromagnetic layer 35 contains at least one element selected from the group consisting of iron (Fe), cobalt (Co), and nickel (Ni). The ferromagnetic layer 35 may contain, as impurities, at least one element selected from the group consisting of boron (B), phosphorus (P), carbon (C), aluminum (Al), silicon (Si), tantalum (Ta), molybdenum (Mo), chromium (Cr), hafnium (Hf), tungsten (W), and titanium (Ti). Specifically, the ferromagnetic layer 35 may contain cobalt iron boron (CoFeB) or iron boride (FeB).

The non-magnetic layer 36 is a non-magnetic oxide. The non-magnetic layer 36 is used as an oxide cap layer OxCP for the ferromagnetic layer 35 (storage layer SL). The non-magnetic layer 36 (oxide cap layer OxCP) is in contact with the ferromagnetic layer 35 (storage layer SL). The non-magnetic layer 36 can improve the perpendicular magnetic anisotropy of the ferromagnetic layer 35. The non-magnetic layer 36 contains an oxide, such as magnesium oxide (MgO), aluminum oxide (Al₂O₃), or a rare earth oxide. The non-magnetic layer 36 may be a mixture of these oxides. That is, the non-magnetic layer 36 is not limited to a binary compound consisting of two kinds of elements, but may include a ternary compound consisting of three kinds of elements, for example, magnesium aluminum oxide (MgAl₂O₄). The non-magnetic layer 36 contains at least one element selected from the group consisting of, for example, iridium (Ir), platinum (Pt), and ruthenium (Ru).

The non-magnetic layer 37 is a non-magnetic conductor. The non-magnetic layer 37 is used as a metal cap layer MCP for the ferromagnetic layer 35 (storage layer SL). The non-magnetic layer 37 includes non-magnetic layers 37a, 37b and 37c. The non-magnetic layer 37a is provided above the non-magnetic layer 36. The non-magnetic layer 37b is provided above the non-magnetic layer 37a. The non-magnetic layer 37c is provided above the non-magnetic layer 37b. In other words, the non-magnetic layer 37a is provided between the non-magnetic layer 36 and the non-magnetic layer 37b. The non-magnetic layer 37b is provided between the non-magnetic layer 37a and the non-magnetic layer 37c. In the description below, the non-magnetic layers 37a, 37b, and 37c will be also referred to as a first metal cap layer MCP1, a second metal cap layer MCP2 and a third metal cap layer MCP3, respectively.

The non-magnetic layer 37a (first metal cap layer MCP1) and the non-magnetic layer 37b (second metal cap layer MCP2) can have, for example, a function to improve the characteristics of the MTJ element, a function as a hard mask, or a function as an electrode. The non-magnetic layer 37a contains, for example, tantalum (Ta). The non-magnetic layer 37b contains, for example, a compound (HfB) of hafnium (Hf) and boron (B), or hafnium (Hf). Since the non-magnetic layer 37b contains a hard material such as a hafnium boron compound (HfB) or hafnium (Hf), i.e., a material with high hardness, the defect occurrence rate can be reduced in the MTJ element.

The non-magnetic layer 37c (third metal cap layer MCP3) can be used as an electrode that improves the electrical coupling between the variable resistance element VR and an upper element (e.g., switching element SE) or a conductive layer (e.g., bit line BL) 20. The non-magnetic layer 37c contains at least one element selected from the group consisting of ruthenium (Ru), platinum (Pt), tungsten (W) and tantalum (Ta).

The variable resistance element VR described above functions as a perpendicular magnetization type MTJ element utilizing the TMR (tunneling magnetoresistance) effect. The variable resistance element VR can be in either a low resistance state or a high resistance state, depending on the relative relationship between the magnetization directions of the ferromagnetic layer 33 (reference layer RL) and the ferromagnetic layer 35 (storage layer SL). Specifically, the variable resistance element VR is in a high resistance state in a case where the magnetization directions of the reference layer RL and the storage layer SL are in an antiparallel state (AP state), and is in a low resistance state in a case where the magnetization directions of the reference layer RL and the storage layer SL are in a parallel state (P state).

The magnetic memory device 1 can store desired data in the memory cell MC by fixing the magnetization direction of the ferromagnetic layer 33 (reference layer RL) and changing the magnetization direction of the ferromagnetic layer 35 (storage layer SL). Specifically, the magnetic memory device 1 controls the magnetization direction of the storage layer SL by causing a write current to flow through the variable resistance element VR, thereby injecting a spin torque into the storage layer SL and the reference layer RL. This method of writing is referred to as a “spin transfer torque writing method.”

In this example, the variable resistance element VR is in the AP state in a case where a write current flows from the ferromagnetic layer 33 toward the ferromagnetic layer 35, and is in the P state in a case where a write current flows from the ferromagnetic layer 35 toward the ferromagnetic layer 33. The variable resistance element VR is configured such that the magnetization direction of the ferromagnetic layer 33 does not change when a current of a magnitude capable of reversing the magnetization direction of the ferromagnetic layer 35 flows through the variable resistance element VR. In other words, the phrase “the magnetization direction is fixed” means that the magnetization direction of the ferromagnetic layer 33 does not vary due to a current of a magnitude capable of reversing the magnetization direction of the ferromagnetic layer 35.

The variable resistance element VR may include other layers, and each ferromagnetic layer and each non-magnetic layer may be composed of a plurality of layers.

### 1.2.4 Comparison of Characteristics Based on Differences in Metal Cap Layers

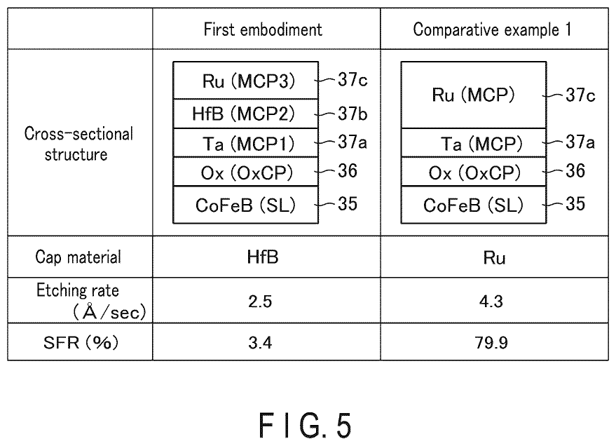

Using comparative example 1 for the first embodiment, the changes in the characteristics of the variable resistor elements VR (MTJ elements) due to the differences in the metal cap layers will be described. FIG. 5 is a diagram showing the cross-sectional structures and characteristics of the metal cap layers in the first embodiment and comparative example 1. Each of the cross-sectional structures in FIG. 5 shows an excerpt of the layer structure corresponding to the variable resistor elements VR formed on silicon substrates, including the ferromagnetic layers 35 (storage layers SL), non-magnetic layers 36 (cap layers OxCP) and non-magnetic layers 37 (metal cap layers MCP).

As shown in FIG. 5, cobalt iron boron (CoFeB) is used for the ferromagnetic layers 35 (storage layers SL) of both the first embodiment and comparative example 1. An oxide is used for the non-magnetic layers 36 (cap layers OxCP) of both the first embodiment and comparative example 1. In the first embodiment and comparative example 1, the layers other than the non-magnetic layers 37 (metal cap layers MCP) are made of similar materials.

The metal cap layers MCP of the first embodiment and comparative example 1 have different structures. In the first embodiment, a metal cap layer MCP1 containing tantalum (Ta), a metal cap layer MCP2 containing a hafnium boron compound (HfB), and a metal cap layer MCP3 containing ruthenium (Ru) are provided in this order above the cap layer OxCP. In comparative example 1, a metal cap layer MCP containing tantalum (Ta) and a metal cap layer MCP containing ruthenium (Ru) are provided in this order above the cap layer OxCP.

The etching rate of the metal cap layer MCP2 containing the hafnium boron compound (HfB) in the first embodiment is about 2.5 (Å/sec). The etching rate of the metal cap layer MCP containing ruthenium (Ru) in comparative example 1 is about 4.3 (Å/sec).

The shunt fail rate (SFR) of the memory cell MC of the magnetic memory device 1 of the first embodiment is about 3.4 percent. In contrast, the SFR of the memory cell of comparative example 1 is approximately 79.9 percent. The SFR represents a defect occurrence rate caused by short circuits between the storage layer SL and reference layer RL in the MTJ element.

Based on the above, it can be understood that in the first embodiment, which includes the metal cap layer MCP2 containing a hard material such as hafnium boride (HfB), the SFR in the memory cell MC can be reduced compared to comparative example 1, which does not include a metal cap layer of hafnium boride compound (HfB).

### 1.3 Advantages of First Embodiment

The magnetic memory device 1 of the first embodiment can reduce the defect occurrence rate of memory cells and improve the performance of the memory cells.

Detailed advantages of the first embodiment will be described below.

As a method to increase the storage capacity of a magnetic memory device, it is conceivable to arrange memory cells MC at a high density by miniaturizing the memory cells MC and reducing the pitch of the memory cell MC arrangement. With such miniaturization and reduced pitch of the memory cells MC arrangement, the defect occurrence rate of the memory cells MC in the magnetic memory device may increase. Therefore, reducing the SFR in the magnetic memory device is required.

In contrast, the configuration of the first embodiment includes a metal cap layer MCP2 containing hafnium boride (HfB) or hafnium (Hf) and provided above the storage layer SL. This enables the SFR in the memory cells MC to be reduced. Therefore, the defect occurrence rate of the memory cells MC in the magnetic memory device can be reduced and the performance of the memory cells can be improved.

### 2. SECOND EMBODIMENT

Next, a magnetic storage device of the second embodiment will be described. The configuration of the memory system, the circuit configuration of the memory cell array, and the structure of the memory cell array in the second embodiment are similar to those in the first embodiment. In the embodiments below, these configurations are similar to those in the first embodiment; therefore, a description of them will be omitted. In connection with the second embodiment, a variable resistance element VR different from that of the first embodiment will be described. In the variable resistance element VR of the second embodiment, the non-magnetic layer 30 (buffer layer BL) contains silicon (Si), and the non-magnetic layer 37 (metal cap layer MCP) contains molybdenum (Mo).

### 2.1 Cross-Sectional Structure of Variable Resistance Element

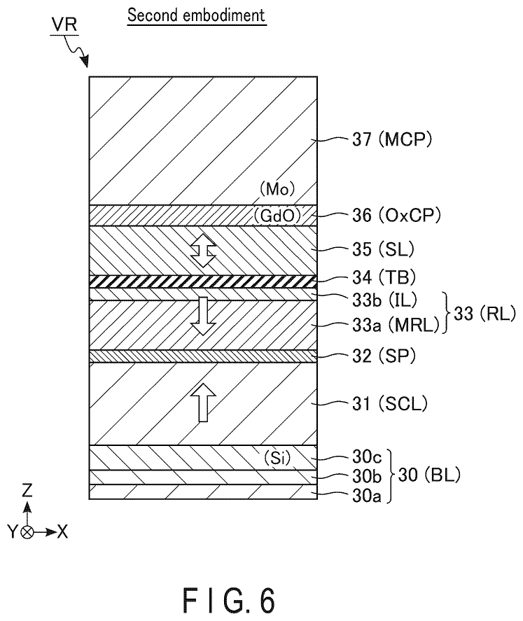

The cross-sectional structure of the variable resistance element VR of the second embodiment will be described below with reference to FIG. 6. FIG. 6 is a cross-sectional view of the variable resistance element VR included in the memory cell MC of the magnetic memory device 1 of the second embodiment.

As shown in FIG. 6, the variable resistance element VR includes, for example, a non-magnetic layer 30, a ferromagnetic layer 31, a non-magnetic layer 32, a ferromagnetic layer 33, a non-magnetic layer 34, a ferromagnetic layer 35, a non-magnetic layer 36, and a non-magnetic layer 37. Of these layers, those that are similar to the layers of the first embodiment will be omitted from the description below, and the layers that have different configurations and materials from the first embodiment will be mainly described.

The non-magnetic layer 30 is a non-magnetic conductor. The non-magnetic layer (buffer layer BL) 30 functions as a layer for controlling the ferromagnetic layer 31 formed thereon to have a desired crystal orientation, and also functions as a layer for suppressing material diffusion into the ferromagnetic layer 31. The non-magnetic layer 30 includes a first layer 30a, a second layer 30b, and a third layer 30c. The second layer 30b is provided above the first layer 30a. The third layer 30c is provided above the second layer 30b. That is, the second layer 30b is provided between the first layer 30a and the third layer 30c. The third layer 30c is provided between the second layer 30b and the ferromagnetic layer 31.

The first layer 30a has an amorphous structure. The first layer 30a contains hafnium (Hf) or hafnium boron (HfB).

The second layer 30b has a body centered cubic (BCC) crystal structure, and has a [110] plane of the BCC crystal structure in the direction perpendicular to the stacking direction of the stacked structure [100]. By using such a second layer 30b, the ferromagnetic layer 31 can be well oriented in the face centered cubic (FCC) [111] plane or the hexagonal close packed (HCP) [0001] plane. This can improve the perpendicular magnetic anisotropy of the ferromagnetic layer 31. The second layer 30b can contain at least one element selected from molybdenum (Mo), tungsten (W), and tantalum (Ta). That is, the second layer 30b may be a molybdenum (Mo) layer, a tungsten (W) layer, or a tantalum (Ta) layer. The second layer 30b may be an alloy layer of two or more elements selected from molybdenum (Mo), tungsten (W), and tantalum (Ta).

The third layer 30c contains silicon (Si) or a silicon compound. For example, the third layer 30c is a layer containing silicon (Si) and boron (B). By providing the third layer 30c, element diffusion caused by heat treatment can be suppressed, and a variable resistance element VR with excellent heat resistance can be obtained. In other words, the deterioration of characteristics due to heat treatment can be suppressed, and the magnetoresistance ratio (MR ratio) in the MTJ element of the variable resistance element VR can be increased. The MR ratio is a value obtained by dividing the change in electrical resistance when the MTJ element transitions from the P state to the AP state by the electrical resistance in the P state. In addition, since the third layer 30c is provided, the perpendicular magnetic anisotropy of the ferromagnetic layer 31 can be improved.

Although the non-magnetic layer 30 is shown as having three layers in the example shown in FIG. 6, it may be a stacked structure made up of two layers or four or more layers.

The non-magnetic layer 36 is a non-magnetic oxide. The non-magnetic layer 36 is used as an oxide cap layer OxCP for the ferromagnetic layer 35 (storage layer SL). The non-magnetic layer 36 is in contact with the ferromagnetic layer 35. The non-magnetic layer 36 can improve the perpendicular magnetic anisotropy of the ferromagnetic layer 35. The non-magnetic layer 36 contains an oxide, such as gadolinium oxide (GdOx), aluminum oxide (Al₂O₃), or a rare earth oxide. The non-magnetic layer 36 may be a mixture of these oxides.

The non-magnetic layer 37 is a non-magnetic conductor. The non-magnetic layer 37 is used as a metal cap layer MCP for the ferromagnetic layer 35 (storage layer SL). The non-magnetic layer 37 can have, for example, a function to improve the characteristics of the MTJ element, a function as a hard mask, or a function as an electrode. The non-magnetic layer 37 contains, for example, molybdenum (Mo).

Since the non-magnetic layer 30 (buffer layer BL) contains silicon (Si) or a silicon compound and the non-magnetic layer 37 (metal cap layer MCP) contains molybdenum (Mo), the magnetoresistance ratio (MR ratio) of the MTJ element is further increased.

### 2.2 Comparison of Characteristics Due to Differences in Metal Cap Layers and Buffer Layers

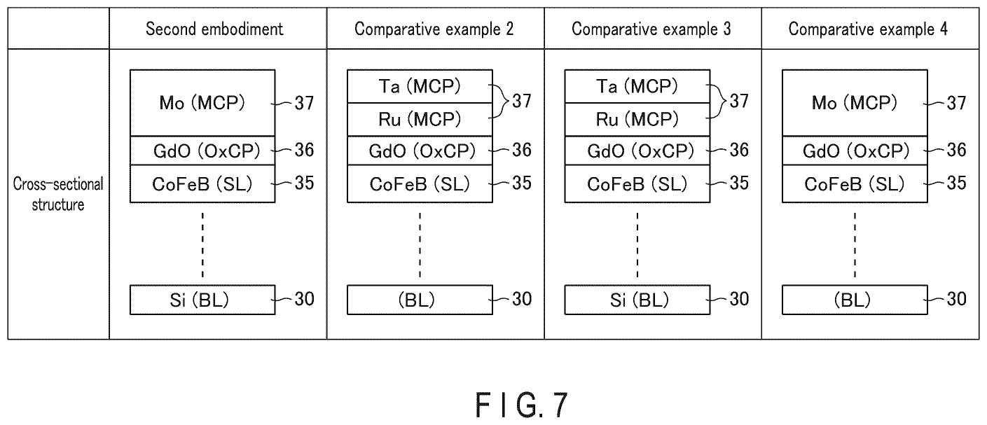

Using comparative example 2-4 for the second embodiment, the changes in the characteristics of the variable resistance elements VR (MTJ elements) due to the differences in the metal cap layers and buffer layers will be described. FIG. 7 is a diagram showing the cross-sectional structures of metal cap layers and buffer layers in the second embodiment and comparative examples 2-4. Each of the cross-sectional structures in FIG. 7 shows an excerpt of the layer structure corresponding to the variable resistance element VR, including the non-magnetic layer 30 (buffer layer BL), ferromagnetic layer 35 (storage layer SL), non-magnetic layer 36 (cap layer OxCP), and non-magnetic layer 37 (metal cap layer MCP).

As shown in FIG. 7, cobalt iron boron (CoFeB) is used for the ferromagnetic layers 35 (storage layers SL) of the second embodiment and comparative examples 2-4. Gadolinium oxide (GdOx) is used for the non-magnetic layers 36 (cap layers OxCP) in the second embodiment and comparative examples 2-4. In the second embodiment and comparative examples 2-4, the layers other than the non-magnetic layers 30 (buffer layers BL) and the non-magnetic layers 37 (metal cap layers MCP) are made of similar materials.

In the second embodiment, a metal cap layer MCP containing molybdenum (Mo) is provided above the cap layer OxCP. Furthermore, a buffer layer BL containing silicon (Si) is provided below the shift canceling layer SCL.

In comparative example 2, a metal cap layer MCP containing ruthenium (Ru) and a metal cap layer MCP containing tantalum (Ta) are provided in this order above the cap layer OxCP. Furthermore, the buffer layer BL provided below the shift canceling layer SCL does not contain silicon (Si).

In comparative example 3, a metal cap layer MCP containing ruthenium (Ru) and a metal cap layer MCP containing tantalum (Ta) are provided in this order above the cap layer OxCP, as in comparative example 2. Furthermore, a buffer layer BL containing silicon (Si) is provided below the shift canceling layer SCL.

In comparative example 4, a metal cap layer MCP containing molybdenum (Mo) is provided above the cap layer OxCP. Furthermore, the buffer layer BL provided below the shift canceling layer SCL does not contain silicon (Si).

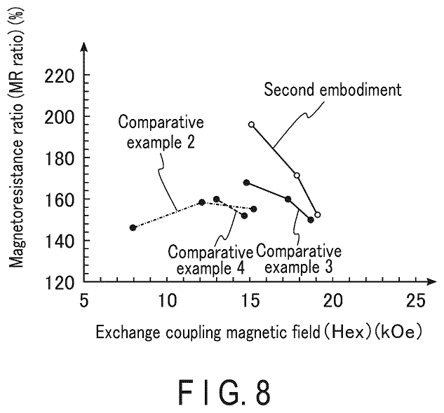

The magnetoresistance ratios in the second embodiment and comparative example 2-4 will be described below with reference to FIG. 8. FIG. 8 is a diagram showing relationships between exchange coupling magnetic fields and magnetoresistance ratios in the second embodiment and comparative examples 2-4. In FIG. 8, the horizontal axis represents the exchange coupling magnetic field (Hex) (kOe), and the vertical axis represents the magnetoresistance ratio (%). The exchange coupling magnetic field represents the strength of the magnetic field that fixes the reference layer RL in the SAF structure including the shift canceling layer SCL and the reference layer RL.

In comparative example 2, the buffer layer BL does not contain silicon (Si), and the metal cap layer MCP does not contain molybdenum (Mo). As shown in FIG. 8, comparative example 2 has a weaker exchange coupling magnetic field and a smaller magnetoresistance ratio than those of the second embodiment and comparative example 3.

In comparative example 3, the buffer layer BL contains silicon (Si), and the metal cap layer MCP does not contain molybdenum (Mo). As shown in FIG. 8, the exchange coupling magnetic field of comparative example 3 is stronger than those of comparative examples 2 and 4 and is weaker than that of the second embodiment, and the magnetoresistance ratio is smaller.

In comparative example 4, the buffer layer BL does not contain silicon (Si), and the metal cap layer MCP contains molybdenum (Mo). As shown in FIG. 8, the exchange coupling magnetic field of comparative example 4 is weaker than those of the second embodiment and comparative example 3, and the magnetoresistance ratio is smaller.

In the second embodiment, the buffer layer BL contains silicon (Si), and the metal cap layer MCP contains molybdenum (Mo). As shown in FIG. 8, the exchange coupling magnetic field of the second embodiment is stronger than those of comparative examples 2-4, and the magnetoresistance ratio is larger.

In more detail, the second embodiment is provided with the buffer layer BL containing silicon (Si), so that the heat resistances of the shift canceling layer SCL and the reference layer RL constituting the SAF structure can be improved. Furthermore, since the metal cap layer MCP containing molybdenum (Mo) is provided, the heat resistance of the storage layer SL can be improved. As a result, in the variable resistance element VR of the second embodiment, both the exchange coupling magnetic field and the magnetoresistance ratio can be improved.

### 2.3 Advantages of Second Embodiment

The magnetic memory device 1 of the second embodiment can improve the performance of the memory cells.

Detailed advantages of the second embodiment will be described below.

As a method to increase the storage capacity of a magnetic memory device, it is conceivable to arrange memory cells MC at a high density by miniaturizing the memory cells MC and reducing the pitch of the memory cell MC arrangement. With such miniaturization and reduced pitch of the memory cell MC arrangement, the magnetoresistance ratio in the memory cell MC may decrease. For this reason, the magnetoresistance ratio in the memory cell MC has to be increased.

In contrast, the configuration of the second embodiment includes a buffer layer BL containing silicon (Si) and provided below the shift canceling layer SCL, and a metal cap layer MCP containing molybdenum (Mo) and provided above the storage layer SL. This enables the magnetoresistance ratio to be increased while maintaining the strength of the exchange coupling magnetic field. Therefore, the performance of the memory cell MC in the magnetic memory device can be improved.

### 3. THIRD EMBODIMENT

Next, a magnetic storage device of the third embodiment will be described. In connection with the third embodiment, a variable resistance element VR different from those of the first and second embodiments will be described. In the variable resistance element VR of the third embodiment, the non-magnetic layer 36 (cap layer OxCP) contains magnesium oxide (MgO), and the non-magnetic layer 37 (metal cap layer MCP) contains molybdenum (Mo).

### 3.1 Cross-Sectional Structure of Variable Resistance Element

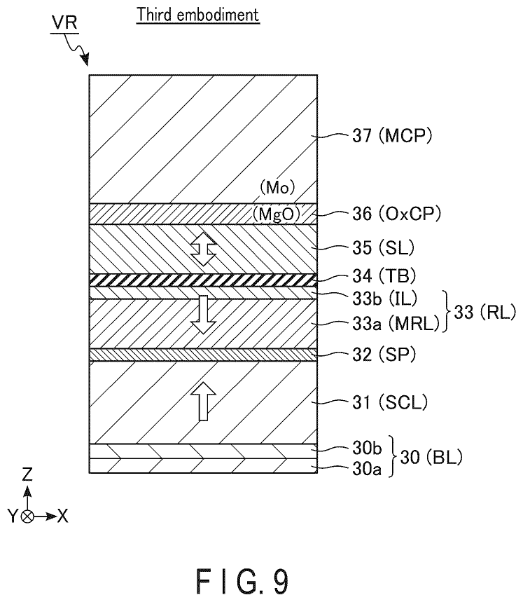

The cross-sectional structure of the variable resistance element VR of the third embodiment will be described below with reference to FIG. 9. FIG. 9 is a cross-sectional view of the variable resistance element VR included in the memory cell MC of the magnetic memory device 1 of the third embodiment.

As shown in FIG. 9, the variable resistance element VR includes, for example, a non-magnetic layer 30, a ferromagnetic layer 31, a non-magnetic layer 32, a ferromagnetic layer 33, a non-magnetic layer 34, a ferromagnetic layer 35, a non-magnetic layer 36, and a non-magnetic layer 37. In the description below, a description of the layers similar to those of the first embodiment will be omitted, and the layers having configurations and materials different from those of the first embodiment will be mainly described.

The non-magnetic layer 36 is a non-magnetic oxide. The non-magnetic layer 36 is used as an oxide cap layer OxCP for the ferromagnetic layer 35 (storage layer SL). The non-magnetic layer 36 is in contact with the ferromagnetic layer 35. The non-magnetic layer 36 can improve the perpendicular magnetic anisotropy of the ferromagnetic layer 35. The non-magnetic layer 36 contains, for example, magnesium oxide (MgO).

The non-magnetic layer 37 is a non-magnetic conductor. The non-magnetic layer 37 is used as a metal cap layer MCP for the ferromagnetic layer 35 (storage layer SL). The non-magnetic layer 37 can have, for example, a function to improve the characteristics of the MTJ element, a function as a hard mask, or a function as an electrode. The non-magnetic layer 37 contains, for example, molybdenum (Mo).

Since the non-magnetic layer 36 (cap layer OxCP) contains magnesium oxide (MgO) and the non-magnetic layer 37 (metal cap layer MCP) contains molybdenum (Mo), the anisotropic magnetic field of the storage layer SL in the MTJ element can be increased.

### 3.2 Comparison of Characteristics Due to Differences in Metal Cap Layers and Oxide Cap Layers

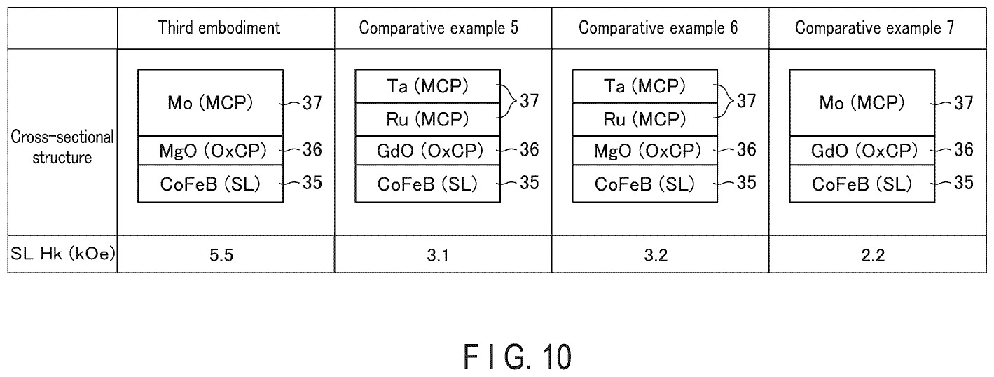

Using comparative example 5-7 for the third embodiment, the changes in the characteristics of the variable resistance elements VR (MTJ elements) due to the differences in the metal cap layers and oxide cap layers will be described. FIG. 10 is a diagram showing cross-sectional structures and characteristics of metal cap layers and oxide cap layers in the third embodiment and comparative examples 5-7. Each of the cross-sectional structures in FIG. 10 shows an excerpt of the layer structure corresponding to the variable resistance element VR, including the ferromagnetic layer 35 (storage layer SL), non-magnetic layer 36 (cap layer OxCP), and non-magnetic layer 37 (metal cap layer MCP).

As shown in FIG. 10, cobalt iron boron (CoFeB) is used for the ferromagnetic layers 35 (storage layers SL) of the third embodiment and comparative examples 5-7. In the third embodiment and comparative examples 5-7, the layers other than the non-magnetic layers 36 (cap layers OxCP) and the non-magnetic layers 37 (metal cap layers MCP) are made of similar materials.

In the third embodiment, a cap layer OxCP containing magnesium oxide (MgO) is provided above the storage layer SL. Furthermore, a metal cap layer MCP containing molybdenum (Mo) is provided above the cap layer OxCP.

In comparative example 5, a cap layer OxCP containing gadolinium oxide (GdOx) is provided above the storage layer SL. Furthermore, a metal cap layer MCP containing ruthenium (Ru) and a metal cap layer MCP containing tantalum (Ta) are provided in this order above the cap layer OxCP.

In comparative example 6, a cap layer OxCP containing magnesium oxide (MgO) is provided above the storage layer SL. Furthermore, a metal cap layer MCP containing ruthenium (Ru) and a metal cap layer MCP containing tantalum (Ta) are provided in this order above the cap layer OxCP.

In comparative example 7, a cap layer OxCP containing gadolinium oxide (GdOx) is provided above the storage layer SL. Furthermore, a metal cap layer MCP containing molybdenum (Mo) is provided above the cap layer OxCP.

As shown in FIG. 10, the anisotropic magnetic field of the storage layer SL in the third embodiment is about 5.5 (kOe). The anisotropic magnetic fields of the storage layers SL in comparative examples 5, 6 and 7 are about 3.1 (kOe), 3.2 (kOe), and 2.2 (kOe), respectively. These anisotropic magnetic fields are values obtained when the product of the saturation magnetic field of the storage layer (SL) and its film thickness (i.e., thickness in the Z direction) is constant.

In both comparative example 5 and comparative example 6, the metal cap layer MCP includes a layer containing ruthenium (Ru) and a layer containing tantalum (Ta), in comparative example 5, the cap layer OxCP contains gadolinium oxide (GdOx), and in comparative example 6, the cap layer OxCP contains magnesium oxide (MgO). The anisotropy magnetic fields of the storage layers SL in comparative examples 5 and 6 of the configurations described above are approximately equal and cannot be increased.

In the third embodiment, since a cap layer OxCP containing magnesium oxide (MgO) and a metal cap layer MCP containing molybdenum (Mo) are provided, the anisotropy magnetic field of the storage layer SL can be increased compared to those of comparative examples 5-7. As can be seen from comparative example 7, even if a metal cap layer MCP containing molybdenum (Mo) is provided, a cap layer OxCP containing magnesium oxide (MgO) must also be provided in order to increase the anisotropy magnetic field of the storage layer SL.

### 3.3 Advantages of Third Embodiment

The magnetic memory device 1 of the third embodiment can improve the performance of the memory cells.

Detailed advantages of the third embodiment will be described below.

As a method to increase the storage capacity of a magnetic memory device, it is conceivable to arrange memory cells MC at a high density by miniaturizing the memory cells MC and reducing the pitch of the memory cell MC arrangement. With such miniaturization and reduced pitch of the memory cell MC arrangement, the thermal stability of the memory cells MC may deteriorate. For this reason, the thermal stability of the memory cells MC has to be improved.

In contrast, the configuration of the third embodiment is provided with a cap layer OxCP containing magnesium oxide (MgO) and provided above the storage layer SL, and a metal cap layer MCP containing molybdenum (Mo) and provided above the cap layer OxCP. This can increase the anisotropic magnetic field of the storage layer SL. As a result, the thermal stability of the memory cells can be increased and the performance of the memory cells can be improved.

### 4. FOURTH EMBODIMENT

Next, a magnetic storage device of the fourth embodiment will be described. In connection with the fourth embodiment, a variable resistance element VR having the configuration described in the first, second, and third embodiments will be described.

In the variable resistance element VR of the fourth embodiment, the non-magnetic layer 30 (buffer layer BL) contains silicon (Si), the non-magnetic layer 36 (cap layer OxCP) contains magnesium oxide (MgO), the non-magnetic layer 37a (metal cap layer MCP1) contains molybdenum (Mo), the non-magnetic layer 37b (metal cap layer MCP2) contains hafnium boron compound (HfB) or hafnium (Hf), and the non-magnetic layer 37c (metal cap layer MCP3) contains ruthenium (Ru).

### 4.1 Cross-Sectional Structure of Variable Resistance Element

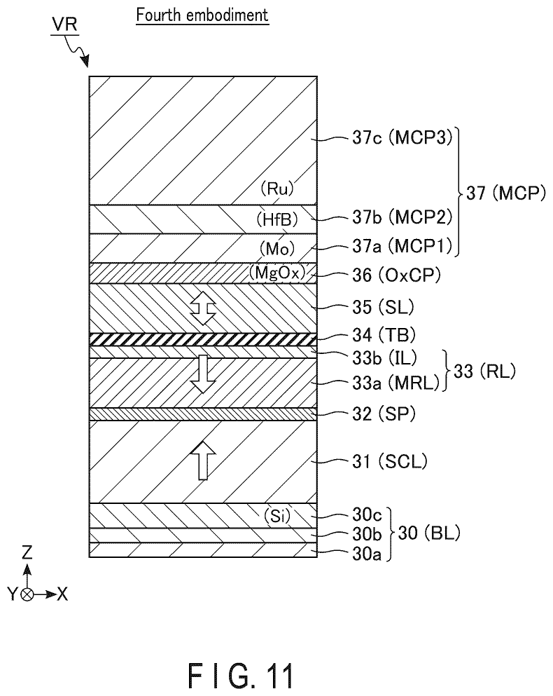

The cross-sectional structure of the variable resistance element VR of the fourth embodiment will be described below with reference to FIG. 11. FIG. 11 is a cross-sectional view of the variable resistance element VR included in the memory cell MC of the magnetic memory device 1 of the fourth embodiment.

As shown in FIG. 11, the variable resistance element VR includes, for example, a non-magnetic layer 30, a ferromagnetic layer 31, a non-magnetic layer 32, a ferromagnetic layer 33, a non-magnetic layer 34, a ferromagnetic layer 35, a non-magnetic layer 36, a non-magnetic layer 37a, a non-magnetic layer 37b, and a non-magnetic layer 37c.

The non-magnetic layer 30, the ferromagnetic layer 31, the non-magnetic layer 32, the ferromagnetic layer 33, the non-magnetic layer 34, the ferromagnetic layer 35, the non-magnetic layer 36, the non-magnetic layer 37a, the non-magnetic layer 37b, and the non-magnetic layer 37c are stacked in this order from the conductive layer 20 (bit line BL) side toward the conductive layer 21 (word line WL) side (in the Z direction).

Specifically, the non-magnetic layer 30 is provided above the conductive layer 20 (in the Z direction). The ferromagnetic layer 31 is provided above the non-magnetic layer 30. The non-magnetic layer 32 is provided above the ferromagnetic layer 31. The ferromagnetic layer 33 is provided above the non-magnetic layer 32. The non-magnetic layer 34 is provided above the ferromagnetic layer 33. The ferromagnetic layer 35 is provided above the non-magnetic layer 34. The non-magnetic layer 36 is provided above the ferromagnetic layer 35. The non-magnetic layer 37a is provided above the non-magnetic layer 36. The non-magnetic layer 37b is provided above the non-magnetic layer 37a. The non-magnetic layer 37c is provided above the non-magnetic layer 37b. The conductive layer 21 is provided above the non-magnetic layer 37c.

In other words, the ferromagnetic layer 33 is provided between the ferromagnetic layer 31 and the ferromagnetic layer 35. The non-magnetic layer 34 is provided between the ferromagnetic layer 33 and the ferromagnetic layer 35. The non-magnetic layer 32 is provided between the ferromagnetic layer 31 and the ferromagnetic layer 33. The ferromagnetic layer 31 is provided between the non-magnetic layer 30 and the non-magnetic layer 32. The non-magnetic layer 30 is provided between the conductive layer 20 and the ferromagnetic layer 31. The ferromagnetic layer 35 is provided between the non-magnetic layer 34 and the non-magnetic layer 36. The non-magnetic layer 36 is provided between the ferromagnetic layer 35 and the non-magnetic layer 37a. The non-magnetic layer 37a is provided between the non-magnetic layer 36 and the non-magnetic layer 37b. The non-magnetic layer 37b is provided between the non-magnetic layer 37a and the non-magnetic layer 37c. The non-magnetic layer 37c is provided between the non-magnetic layer 37b and the conductive layer 21.

The non-magnetic layer 30 contains, for example, silicon (Si). The non-magnetic layer 36 (cap layer OxCP) contains, for example, magnesium oxide (MgO). The non-magnetic layer 37a (metal cap layer MCP1) contains, for example, molybdenum (Mo). The non-magnetic layer 37b (metal cap layer MCP2) contains, for example, hafnium boron compound (HfB) or hafnium (Hf). The non-magnetic layer 37c (metal cap layer MCP3) contains, for example, ruthenium (Ru).

Since the advantages of the fourth embodiment are substantially similar to those of the first, second, and third embodiments, a description of the advantages will be omitted here.

### 5. FIFTH EMBODIMENT

Next, a magnetic storage device of the fifth embodiment will be described. In connection with the fifth embodiment, a variable resistance element VR having the configuration described in the first and second embodiments will be described.

In the variable resistance element VR of the fifth embodiment, the non-magnetic layer 30 (buffer layer BL) contains silicon (Si), the non-magnetic layer 37a (metal cap layer MCP1) contains molybdenum (Mo), the non-magnetic layer 37b (metal cap layer MCP2) contains hafnium boron compound (HfB) or hafnium (Hf), and the non-magnetic layer 37c (metal cap layer MCP3) contains ruthenium (Ru).

### 5.1 Cross-Sectional Structure of Variable Resistance Element

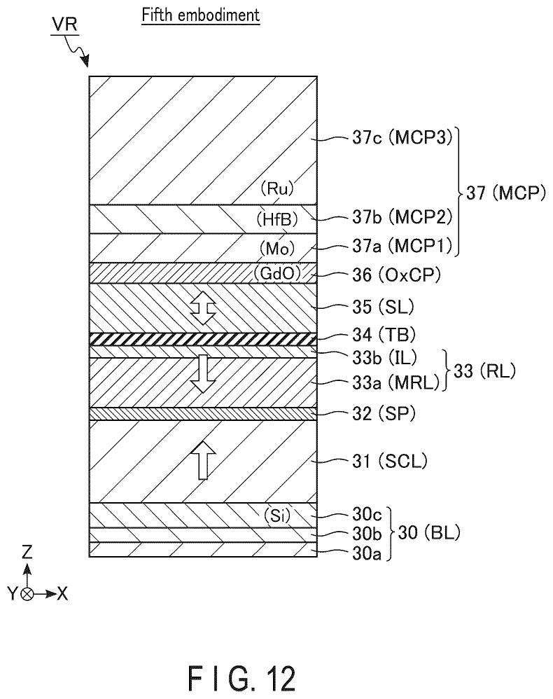

The cross-sectional structure of the variable resistance element VR of the fifth embodiment will be described below with reference to FIG. 12. FIG. 12 is a cross-sectional view of the variable resistance element VR included in the memory cell MC of the magnetic storage device 1 of the fifth embodiment.

The stacked structure of the fifth embodiment shown in FIG. 12 is similar to that of the fourth embodiment shown in FIG. 11. The non-magnetic layer 36 (cap layer OxCP) contains, for example, gadolinium oxide (GdOx). The configurations and materials of the other ferromagnetic layers and non-magnetic layers are similar to those of the fourth embodiment.

Since the advantages of the fifth embodiment are substantially similar to those of the first and second embodiments, a description of the advantages will be omitted here.

### 6. SIXTH EMBODIMENT

Next, a magnetic storage device of the sixth embodiment will be described. In connection with the sixth embodiment, a variable resistance element VR having the configuration described in the second and third embodiments will be described.

In the variable resistance element VR of the sixth embodiment, the non-magnetic layer 30 (buffer layer BL) contains silicon (Si), the non-magnetic layer 36 (cap layer OxCP) contains magnesium oxide (MgO), and the non-magnetic layer 37 (metal cap layer MCP) contains molybdenum (Mo).

### 6.1 Cross-Sectional Structure of Variable Resistance Element

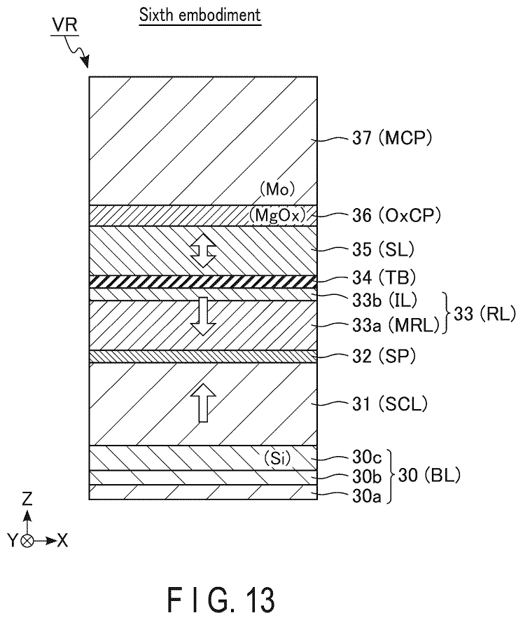

The cross-sectional structure of the variable resistance element VR of the sixth embodiment will be described below with reference to FIG. 13. FIG. 13 is a cross-sectional view of the variable resistance element VR included in the memory cell MC of the magnetic memory device 1 of the sixth embodiment.

As shown in FIG. 13, the variable resistance element VR includes, for example, a non-magnetic layer 30, a ferromagnetic layer 31, a non-magnetic layer 32, a ferromagnetic layer 33, a non-magnetic layer 34, a ferromagnetic layer 35, a non-magnetic layer 36, and a non-magnetic layer 37.

The non-magnetic layer 30, the ferromagnetic layer 31, the non-magnetic layer 32, the ferromagnetic layer 33, the non-magnetic layer 34, the ferromagnetic layer 35, the non-magnetic layer 36 and the non-magnetic layer 37 are stacked in this order from the conductive layer 20 (bit line BL) side toward the conductive layer 21 (word line WL) side (in the Z direction).

Specifically, the non-magnetic layer 30 is provided above the conductive layer 20 (in the Z direction). The ferromagnetic layer 31 is provided above the non-magnetic layer 30. The non-magnetic layer 32 is provided above the ferromagnetic layer 31. The ferromagnetic layer 33 is provided above the non-magnetic layer 32. The non-magnetic layer 34 is provided above the ferromagnetic layer 33. The ferromagnetic layer 35 is provided above the non-magnetic layer 34. The non-magnetic layer 36 is provided above the ferromagnetic layer 35. The non-magnetic layer 37 is provided above the non-magnetic layer 36. The conductive layer 21 is provided above the non-magnetic layer 37.

In other words, the ferromagnetic layer 33 is provided between the ferromagnetic layer 31 and the ferromagnetic layer 35. The non-magnetic layer 34 is provided between the ferromagnetic layer 33 and the ferromagnetic layer 35. The non-magnetic layer 32 is provided between the ferromagnetic layer 31 and the ferromagnetic layer 33. The ferromagnetic layer 31 is provided between the non-magnetic layer 30 and the non-magnetic layer 32. The non-magnetic layer 30 is provided between the conductive layer 20 and the ferromagnetic layer 31. The ferromagnetic layer 35 is provided between the non-magnetic layer 34 and the non-magnetic layer 36. The non-magnetic layer 36 is provided between the ferromagnetic layer 35 and the non-magnetic layer 37. The non-magnetic layer 37 is provided between the non-magnetic layer 36 and the conductive layer 21.

The non-magnetic layer 30 contains, for example, silicon (Si). The non-magnetic layer 36 (cap layer OxCP) contains, for example, magnesium oxide (MgO). The non-magnetic layer 37 (metal cap layer MCP) contains, for example, molybdenum (Mo).

Since the advantages of the sixth embodiment are substantially similar to those of the second and third embodiments, a description of the advantages will be omitted here.

### 7. OTHERS

In connection with each of the above embodiments, the magnetic memory device 1 was described as an example of a magnetic device including an MTJ element (variable resistance element VR), but this is not restrictive. The magnetic device may be another type of device that requires a magnetic element having perpendicular magnetic anisotropy, such as a sensor or media. It suffices that the magnetic element in question uses at least a variable resistance element (VR).

In the present specification, the term “coupling” means that elements are electrically coupled, and does not exclude the case where another element is interposed in between. Each of the non-magnetic layers 32 and 37 may be referred to as a “conductive layer.” The non-magnetic layer 34 may be referred to as an “oxide layer.” The non-magnetic layer 36 may be referred to as an “oxide layer.” The elements contained in each layer of the MTJ element can be measured, for example, by electron energy loss spectroscopy (EELS) using a scanning transmission electron microscope (STEM).

While certain embodiments have been described, these embodiments have been presented by way of example only, and are not intended to limit the scope of the embodiments. Indeed, these embodiments can be embodied in a variety of other forms; furthermore, various omissions, substitutions and changes in the form of the embodiments described herein may be made without departing from the spirit. The accompanying claims and their equivalents are intended to cover such forms or modifications as would fall within the scope and spirit.

What is claimed is:

1. A magnetic memory device comprising:
a first non-magnetic layer including silicon (Si);
a first ferromagnetic layer provided above the first non-magnetic layer;
a second non-magnetic layer provided above the first ferromagnetic layer;
a second ferromagnetic layer provided above the second non-magnetic layer;
a third non-magnetic layer provided above the second ferromagnetic layer;
a third ferromagnetic layer provided above the third non-magnetic layer;
a fourth non-magnetic layer provided above the third ferromagnetic layer and including magnesium (Mg) and oxygen (O);
a fifth non-magnetic layer provided above the fourth non-magnetic layer and including molybdenum (Mo);
a sixth non-magnetic layer provided above the fifth non-magnetic layer and including hafnium (Hf); and
a seventh non-magnetic layer provided above the sixth non-magnetic layer and including ruthenium (Ru).

2. The magnetic memory device according to claim 1, wherein the fourth non-magnetic layer includes at least one element selected from the group consisting of iridium (Ir), platinum (Pt), and ruthenium (Ru).

3. The magnetic memory device according to claim 1, wherein the first non-magnetic layer includes a silicon (Si) compound.

4. The magnetic memory device according to claim 1, wherein the seventh non-magnetic layer includes at least one element selected from the group consisting of platinum (Pt), tungsten (W), tantalum (Ta), and ruthenium (Ru).

5. The magnetic memory device according to claim 1, wherein the sixth non-magnetic layer includes a compound of hafnium (Hf) and boron (B).

6. The magnetic memory device according to claim 1, wherein the fifth non-magnetic layer includes a molybdenum (Mo) compound.

7. The magnetic memory device according to claim 1, wherein the third ferromagnetic layer and the fourth non-magnetic layer are in contact with each other.

8. The magnetic memory device according to claim 1, wherein
the second ferromagnetic layer includes at least one element selected from the group consisting of iron (Fe), cobalt (Co), and nickel (Ni),
the third non-magnetic layer includes at least one element, or an oxide of a compound thereof, selected from the group consisting of magnesium (Mg), aluminum (Al), zinc (Zn), titanium (Ti), and LSM (Lanthanum-strontium-manganese), and
the third ferromagnetic layer includes at least one element selected from the group consisting of iron (Fe), cobalt (Co), and nickel (Ni).

9. The magnetic memory device according to claim 1, wherein
the second non-magnetic layer is antiferromagnetically coupled to the first ferromagnetic layer, and
a magnetization direction of the first ferromagnetic layer is fixed in a direction antiparallel to a magnetization direction of a second ferromagnetic layer.

10. The magnetic memory device according to claim 1, wherein the first ferromagnetic layer includes at least one element selected from the group consisting of iron (Fe), cobalt (Co), and nickel (Ni).

11. The magnetic memory device according to claim 1, wherein the second non-magnetic layer includes at least one element selected from the group consisting of ruthenium (Ru), osmium (Os), iridium (Ir), vanadium (V), and chromium (Cr).

12. The magnetic memory device according to claim 1, wherein
each of the second ferromagnetic layer and the third ferromagnetic layer has an easy magnetization axis direction perpendicular to a film surface,
a magnetization direction of the second ferromagnetic layer is fixed, and
a magnetization direction of the third ferromagnetic layer is configured to be easily reversed compared with that of the second ferromagnetic layer.

13. The magnetic memory device according to claim 1, further comprising:
a first conductive layer extending in a first direction;
a second conductive layer extending in a second direction intersecting the first direction and spaced apart from the first conductive layer; and
a memory cell provided between the first conductive layer and the second conductive layer,
wherein the memory cell includes the first ferromagnetic layer, the second ferromagnetic layer, the third ferromagnetic layer, the first non-magnetic layer, the second non-magnetic layer, the third non-magnetic layer, the fourth non-magnetic layer, the fifth non-magnetic layer, the sixth non-magnetic layer, and the seventh non-magnetic layer.

14. A magnetic memory device comprising:
a first non-magnetic layer including silicon (Si);
a first ferromagnetic layer provided above the first non-magnetic layer;
a second non-magnetic layer provided above the first ferromagnetic layer;
a second ferromagnetic layer provided above the second non-magnetic layer;
a third non-magnetic layer provided above the second ferromagnetic layer;
a third ferromagnetic layer provided above the third non-magnetic layer;
a fourth non-magnetic layer provided above the third ferromagnetic layer;
a fifth non-magnetic layer provided above the fourth non-magnetic layer and including molybdenum (Mo);
a sixth non-magnetic layer provided above the fifth non-magnetic layer and including hafnium (Hf); and
a seventh non-magnetic layer provided above the sixth non-magnetic layer and including ruthenium (Ru).

15. The magnetic memory device according to claim 14, wherein the first non-magnetic layer includes a silicon (Si) compound.

16. The magnetic memory device according to claim 14, wherein the sixth non-magnetic layer includes a compound of hafnium (Hf) and boron (B).

17. The magnetic memory device according to claim 14, wherein the fifth non-magnetic layer includes a molybdenum (Mo) compound.

18. A magnetic memory device comprising:
a first non-magnetic layer including silicon (Si);
a first ferromagnetic layer provided above the first non-magnetic layer;
a second non-magnetic layer provided above the first ferromagnetic layer;
a second ferromagnetic layer provided above the second non-magnetic layer;
a third non-magnetic layer provided above the second ferromagnetic layer;
a third ferromagnetic layer provided above the third non-magnetic layer;
a fourth non-magnetic layer provided above the third ferromagnetic layer and including magnesium (Mg) and oxygen (O); and
a fifth non-magnetic layer provided above the fourth non-magnetic layer and including molybdenum (Mo).

19. The magnetic memory device according to claim 18, wherein the first non-magnetic layer includes a silicon (Si) compound.

20. The magnetic memory device according to claim 18, wherein the fifth non-magnetic layer includes a molybdenum (Mo) compound.
